(19) United States
(12) Patent Application Publication
(10) Pub. No.: US 2010/0300355 A1
(43) Pub. Date: Dec. 2, 2010

(54) PRINTING MATERIAL PROFILES ONTO SUBSTRATES

(75) Inventor: Amitabh Verma, New Delhi (IN)

Correspondence Address: DAVID A. GUERRA;INTERNATIONAL PATENT GROUP, LLC, Suite 700, 1816 Crowchild Trail N.W., CALGARY, AB, T2M 3Y7, CA

(73) Assignee: MOSER BAER INDIA LIMITED, Near Modi Mill Flyover (IN)

(21) Appl. No.: 12/644,265

(22) Filed: Dec. 22, 2009

(30) Foreign Application Priority Data
Jun. 1, 2009 (IN) 1263/CHE/2009

(51) Int. Cl. B05C 11/00

(52) U.S. Cl. 118/696

(57) ABSTRACT

A printing apparatus configured to print a material profile onto a substrate is provided. The printing apparatus includes a container, a nozzle, a positive displacement mechanism, and one or more regulators. The container is adapted to hold a precursor material. The container has a first end and a second end, with the nozzle connected to the first end of the container. The nozzle has an orifice configured to deposit the precursor material over the substrate. The positive displacement mechanism is configured to push the precursor material through the orifice of the nozzle over the substrate. The regulator is configured to deposit the precursor material in accordance with pre-determined parameters governing width and cross-sectional area of the precursor material deposited over the substrate, such that the precursor material deposited over the substrate has a pre-determined width and a pre-determined cross-sectional area.

### CROSS-REFERENCE TO RELATED APPLICATION

This application claims the benefit of priority under 35 U.S.C 119 to co-pending Indian Patent Application No. 1263/CHE/2009 filed on Jun. 1, 2009. The entire disclosure of the prior applications is incorporated herein by reference.

### BACKGROUND OF THE INVENTION

1. Field of the Invention

The present invention relates, in general, to printing. More particularly, the present invention relates to a printing apparatus, method and system for printing a material profile onto a substrate of a photovoltaic device.

2. Description of the Prior Art

Photovoltaic devices convert solar energy into electrical energy by the photovoltaic effect. A typical photovoltaic device may be made by diffusing an n-type impurity in a p-type semiconductor wafer, or by diffusing a p-type impurity in an n-type semiconductor wafer. An anti-reflection coating may be applied on a front surface of the photovoltaic device to reduce reflection losses. The anti-reflection coating may, for example, be made of silicon nitride.

In order to collect current generated in the photovoltaic device, electrical conductors are provided on front and back surfaces of the photovoltaic device. As the front surface of the photovoltaic device receives incident solar energy, the electrical conductors on the front surface are often made in a grid-like pattern of electrically-conductive fingers. In industrial photovoltaic devices, the fingers are typically printed by a screen printing process using a silver paste. The silver paste includes powdered silver, glass frit and an organic binder. The fingers are then fired at a high temperature, so that the glass frit reacts with silicon nitride and facilitates electrical contact between the fingers and the photovoltaic device.

Solar radiation falling on the area exposed between the fingers generates electron-hole pairs as charge carriers. As solar energy incident on the fingers is reflected away, the area over which the fingers are formed remains unexposed to solar radiation, and does not contribute to photovoltaic process. This is often referred to as shadow losses occurring in the photovoltaic device. Therefore, it is desirable to reduce the finger width, to minimize shadow losses. However, attempts to reduce the finger width have resulted in reduction of the cross sectional area of the conductor as well. This may lead to increase in resistance in the electrical conductors. Therefore, it is desirable to reduce the finger width, while ensuring that the cross-sectional area of the fingers would not be compromised on.

In addition, the thickness of semiconductor wafers could be continually decreasing. Excessive pressure on a wafer may introduce micro-cracks in the wafer. Therefore, it is desirable that printing techniques do not exert pressure on a wafer during printing.

Several printing techniques have been employed for reducing the finger width. One of the printing techniques involves inkjet printing. An ink drop is propelled onto the surface to be printed. However, this technique requires use of low viscosity ink and control of ink rheology to avoid smearing. Moreover, the finger height may be inadequate, and has to be increased by another secondary process. In another printing technique, a window is opened in the silicon nitride layer of a semiconductor wafer by photolithography and etching. A seed layer of nickel is then deposited in the opened window by electroless plating. Subsequently, the finger height is built by Light Induced Plating (LIP). In yet another technique, known as jet printing, the ink is converted into an aerosol, and a highly-focused material beam is impinged on the wafer. However, this technique also calls for inks of low viscosity. Furthermore, this technique can be used for depositing a seed layer, which is required to be built by yet another process like LIP.

The conventional techniques, therefore, suffer from one or more disadvantages. Separate processes have to be employed for printing the finger width, and subsequently, increasing the finger height. This makes these techniques complex, tedious, and unsuitable for mass manufacturing. In addition, fluids of different viscosity cannot be handled easily. Moreover, the viscosity of the precursor material has to be changed in some cases.

In light of the foregoing discussion, there is a need for a printing apparatus, method and system for printing a material profile onto a substrate that is suitable for mass manufacturing, is suitable for printing a material profile of desired dimensions, is configured to print the material profile substantially independent of the viscosity of a precursor material, and does not exert substantial pressure on the substrate during printing that could introduce micro-cracks in the substrate. In this regard, the present invention substantially fulfills this need. In this respect, the printing apparatus according to the present invention substantially departs from the conventional concepts and designs of the prior art, and in doing so provides an apparatus primarily developed for the purpose of printing a material profile of desired dimensions.

### SUMMARY OF THE INVENTION

In view of the foregoing disadvantages inherent in the known types of printing apparatuses now present in the prior art, the present invention provides an improved printing apparatus, and overcomes the above-mentioned disadvantages and drawbacks of the prior art. As such, the general purpose of the present invention, which will be described subsequently in greater detail, is to provide a new and improved printing apparatus and system which has all the advantages of the prior art mentioned heretofore and many novel features that result in a material profile which is not anticipated, rendered obvious, suggested, or even implied by the prior art, either alone or in any combination thereof.

An embodiment herein relates to a printing apparatus, method and system for printing a material profile onto a substrate of a photovoltaic device.

Another embodiment herein relates to a printing apparatus that is suitable for mass manufacturing.

Yet another embodiment herein relates to a printing apparatus that is suitable for printing a material profile of desired dimensions.

Still another embodiment herein relates to a printing apparatus that is configured to print a material profile independent of the viscosity of a precursor material.

Yet another embodiment herein relates to a printing apparatus that is configured to not exert substantially any pressure on the substrate during printing.

Embodiments herein provide a printing apparatus, method and system for printing a material profile onto a substrate. The printing apparatus includes a container, a nozzle, a positive displacement mechanism, and one or more regulators. The container has a first end and a second end, and is configured to hold a precursor material. The nozzle is connected to the first end of the container. The nozzle has an orifice through which the precursor material is deposited over the substrate. The positive displacement mechanism is configured to push the precursor material through the orifice of the nozzle over the substrate. The positive displacement mechanism may, for example, include a piston that is movably positioned between the first end and the second end of the container. The regulators are configured to deposit the precursor material in accordance with pre-determined parameters governing width and cross-sectional area of the deposit of the precursor material.

In an embodiment herein, the material profile includes one or more electrical conductors.

In an embodiment herein, the substrate is a substrate of a photovoltaic device.

In accordance with an embodiment herein, the pre-determined parameters include at least one of: the position of the nozzle with respect to the substrate, the path of movement of the nozzle over the substrate, the speed of movement of the nozzle, the size of the orifice of the nozzle, the shape of the orifice of the nozzle, and the rate at which the precursor material is pushed through the orifice of the nozzle.

In accordance with an embodiment herein, a deposit of the precursor material over the substrate has a pre-determined width and a pre-determined cross-sectional area. The pre-determined width and the pre-determined cross-sectional area are user-defined. In an embodiment herein, the printing apparatus could be configured to print material profiles of width ranging between 40 μm and 5 mm.

In accordance with an embodiment herein, the printing apparatus also includes one or more controllers configured to define the pre-determined parameters.

In accordance with an embodiment herein, the printing apparatus includes one or more material regulators configured to alter the properties of the precursor material. The properties of the precursor material are dependent on one or more material parameters, and may be altered by changing at least one of the material parameters. The material parameters may, for example, include the size of particles in the precursor material, the shape of the particles in the precursor material, and the composition of the precursor material. The printing apparatus is configured to print the material profile independent of the viscosity of a precursor material. In an embodiment herein, the printing apparatus could be configured to handle precursor materials of viscosity in the range of 1-300000 centipoises.

In an embodiment herein, the printing apparatus includes one or more indicators configured to provide information about the functioning of the printing apparatus.

In addition, the printing apparatus does not require any contact with the substrate during printing, and therefore, does not exert pressure on the substrate.

Moreover, the printing apparatus does not require separate processes for printing a material profile of a desired width and increasing the height of the material profile. This makes the printing apparatus suitable for mass manufacturing.

There has thus been outlined, rather broadly, the more important features of the invention in order that the detailed description thereof that follows may be better understood and in order that the present contribution to the art may be better appreciated.

Numerous objects, features and advantages of the present invention will be readily apparent to those of ordinary skill in the art upon a reading of the following detailed description of presently preferred, but nonetheless illustrative, embodiments of the present invention when taken in conjunction with the accompanying drawings. In this respect, before explaining the current embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of descriptions and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

These together with other objects of the invention, along with the various features of novelty that characterize the invention, are pointed out with particularity in the claims annexed to and forming a part of this disclosure. For a better understanding of the invention, its operating advantages and the specific objects attained by its uses, reference should be had to the accompanying drawings and descriptive matter in which there are illustrated preferred embodiments of the invention.

### BRIEF DESCRIPTION OF DRAWINGS

Embodiments herein will hereinafter be described in conjunction with the appended drawings provided to illustrate and not to limit the present invention, wherein like designations denote like elements, and in which:

FIG. 1 illustrates a printing apparatus configured to print a material profile onto a substrate of a photovoltaic device, in accordance with an embodiment herein;

FIG. 2 illustrates a printing apparatus configured to print a material profile onto a substrate of a photovoltaic device, in accordance with another embodiment herein;

FIG. 3 illustrates a system for printing a material profile onto a substrate of a photovoltaic device, in accordance with an embodiment herein;

FIG. 4 illustrates the path of movement of a nozzle over a substrate, and

FIG. 5 illustrates material profiles so printed onto the substrate, in accordance with an example embodiment herein;

FIG. 6 illustrates a method of printing a material profile onto a substrate of a photovoltaic device, in accordance with an embodiment herein; and

FIG. 7 illustrates a method of printing a material profile onto a substrate of a photovoltaic device, in accordance with another embodiment herein.

### DETAILED DESCRIPTION

As used in the specification and claims, the singular forms “a”, “an” and “the” include plural references unless the context clearly dictates otherwise. For example, the term “a syringe” may include a plurality of syringes unless the context clearly dictates otherwise. A term having “-containing” such as “metal-containing” contains a metal but is open to other substances, but need not contain any other substance other than a metal.

Embodiments herein provide a printing apparatus, method, system for printing a material profile onto a substrate. In the description herein for embodiments, numerous specific details are provided, such as examples of components and/or mechanisms, to provide a thorough understanding of embodiments. One skilled in the relevant art will recognize, however, that an embodiment can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments.

### GLOSSARY

Photovoltaic device: A photovoltaic device is a packaged interconnected assembly of photovoltaic elements, which converts solar energy into electrical energy by the photovoltaic effect.

Substrate: A substrate is a portion of a photovoltaic device on which a material profile is to be printed.

Material profile: A material profile is a profile that is printed onto the substrate.

Precursor material: A precursor material is a material that is used to print the material profile.

Deposit: A deposit is a material formed by deposition of the precursor material. The deposit solidifies to form the material profile.

Container: A container is a device for holding the precursor material.

Nozzle: A nozzle is a device for depositing the precursor material.

Orifice: An orifice is a hole on the nozzle through which the precursor material is pushed over the substrate.

Positive displacement mechanism: A positive displacement mechanism is a mechanism by which the precursor material is pushed by positive displacement to the orifice of the nozzle.

Regulator: A regulator is a device for ensure deposition of the precursor material in accordance with pre-determined parameters.

Controller: A controller is a device for defining the pre-determined parameters.

Material regulator: A material regulator is a device for altering the properties of the precursor material.

Indicator: An indicator is a device for providing information about the process of printing of the material profile.

The printing apparatus includes a container, a nozzle, a positive displacement mechanism, and one or more regulators. The container has a first end and a second end, and is configured to hold a precursor material. The nozzle is connected to the first end of the container. The nozzle has an orifice through which the precursor material is deposited over the substrate. The positive displacement mechanism is configured to push the precursor material through the orifice of the nozzle over the substrate. The positive displacement mechanism may, for example, include a piston that is movably positioned between the first end and the second end of the container. The regulators are configured to deposit the precursor material in accordance with pre-determined parameters governing width and cross-sectional area of the deposit of the precursor material.

In an embodiment herein, the material profile includes one or more electrical conductors.

In an embodiment herein, the substrate is a substrate of a photovoltaic device.

In accordance with an embodiment herein, the pre-determined parameters include at least one of: the position of the nozzle with respect to the substrate, the path of movement of the nozzle over the substrate, the speed of movement of the nozzle, the size of the orifice of the nozzle, the shape of the orifice of the nozzle, and the rate at which the precursor material is pushed through the orifice of the nozzle.

In accordance with an embodiment herein, a deposit of the precursor material over the substrate has a pre-determined width and a pre-determined cross-sectional area. The pre-determined width and the pre-determined cross-sectional area are user-defined. In an embodiment herein, the printing apparatus could be configured to print material profiles of width ranging between 40 μm and 5 mm.

In accordance with an embodiment herein, the printing apparatus also includes one or more controllers configured to define the pre-determined parameters.

In accordance with an embodiment herein, the printing apparatus includes one or more material regulators configured to alter the properties of the precursor material. The properties of the precursor material are dependent on one or more material parameters. The material parameters may, for example, include the size of particles in the precursor material, the shape of the particles in the precursor material, and the composition of the precursor material. Therefore, the properties of the precursor material may be altered by changing at least one of the material parameters. The printing apparatus could be configured to print the material profile independent of the viscosity of a precursor material. In an embodiment herein, the printing apparatus could be configured to handle precursor materials of viscosity in the range of 1-300000 centipoises.

In an embodiment herein, the printing apparatus includes one or more indicators configured to provide information about the functioning of the printing apparatus.

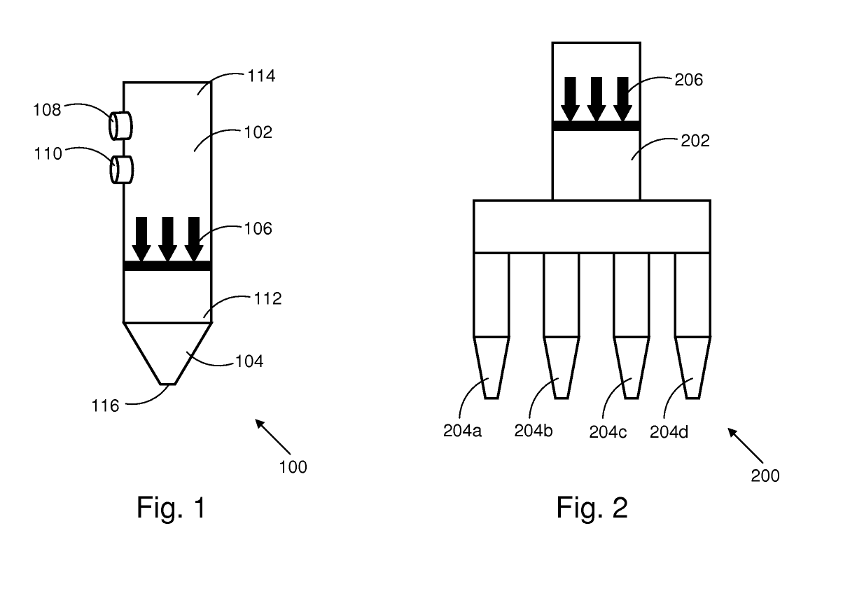

FIG. 1 illustrates a printing apparatus 100 configured to print a material profile onto a substrate of a photovoltaic device, in accordance with an embodiment herein. Printing apparatus 100 includes a container 102, a nozzle 104, a positive displacement mechanism 106, a regulator 108 and a controller 110.

Container 102 is configured to hold a precursor material. Container 102 has a first end 112 and a second end 114. Nozzle 104 is connected to first end 112 of container 102. Nozzle 104 has an orifice 116 through which the precursor material is deposited over the substrate. Orifice 116 may be of any desired shape. For example, orifice 116 may be circular, elliptical or polygonal in shape.

Positive displacement mechanism 106 is configured to push the precursor material through orifice 116 of nozzle 104 over the substrate. Positive displacement mechanism 106 may, for example, include a piston that is movably positioned between first end 112 and second end 114 of container 102. Alternatively, positive displacement mechanism 106 may include a pump that is connected to second end 114 of container 102.

With reference to FIG. 1, container 102 is a hollow tube whose one end is connected to nozzle 104. Container 102 may be of any desired shape. For example, container 102 may be cylindrical in shape. In such a case, nozzle 104 may be conical in shape, and positive displacement mechanism 106 may be configured to substantially fit the circular cross-section of container 102. It should be noted here that container 102, nozzle 104 and positive displacement mechanism 106 may be of any desired shape and size.

The precursor material is deposited over the substrate as described above, thereby printing the material profile onto the substrate. The precursor material may, for example, be a mixture of various constituents. In an embodiment herein, the precursor material includes a metal-containing substance, whereby the material profile so printed includes one or more electrical conductors. Examples of the metal-containing substance include, but are not limited to, metals, such as silver, copper and gold, metal alloys, such as alloys of silver and gold, metal-containing compounds, and particle mixtures of metals and non-metals.

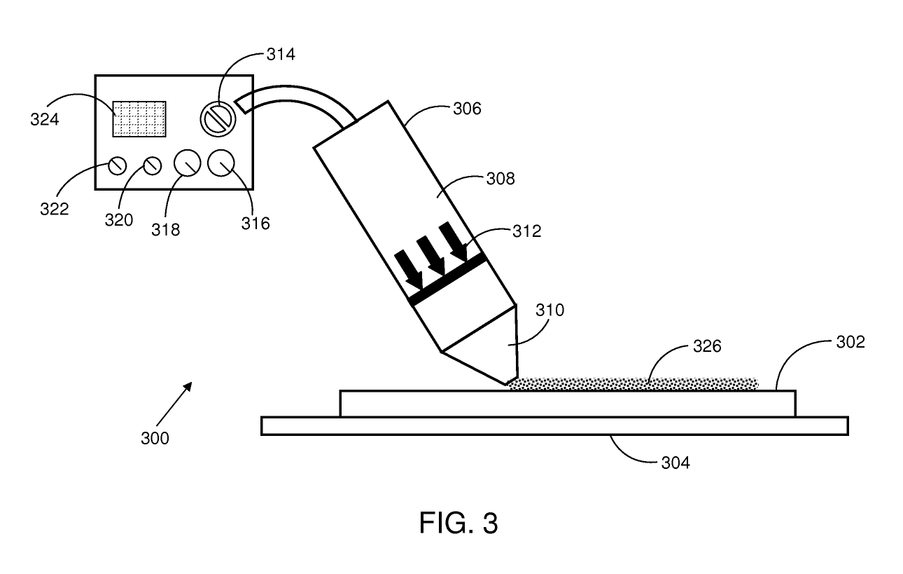

In accordance with an embodiment herein, a deposit of the precursor material over the substrate has a pre-determined width and a pre-determined cross-sectional area. The pre-determined width and the pre-determined cross-sectional area are user-defined. In accordance with an embodiment herein, printing apparatus 100 includes one or more regulators, shown as regulator 108, configured to deposit the precursor material in accordance with pre-determined parameters governing the width and the cross-sectional area of the deposit of the precursor material. These pre-determined parameters may, for example, include at least one of: the position of nozzle 104 with respect to the substrate, the path of movement of nozzle 104 over the substrate, the speed of movement of nozzle 104, the size of orifice 116 of nozzle 104, the shape of orifice 116 of nozzle 104, and the rate at which the precursor material is pushed through orifice 116 of nozzle 104. In accordance with an embodiment herein, printing apparatus 100 also includes one or more controllers, shown as controller 110, configured to define the pre-determined parameters. Details of the pre-determined parameters have been provided in conjunction with FIGS. 3, 4 and 5.

In accordance with an embodiment herein, printing apparatus 100 includes one or more material regulators (not shown in FIG. 1) configured to alter the properties of the precursor material. The properties of the precursor material are dependent on one or more material parameters. Therefore, the properties of the precursor material may be altered by changing at least one of the material parameters. The material parameters may, for example, include the size of particles in the precursor material, the shape of the particles in the precursor material, and the composition of the precursor material. In accordance with an embodiment herein, printing apparatus 100 could be configured to handle precursor materials of viscosity in the range of 1-300000 centipoises.

Printing apparatus 100 could be configured to print thin and high aspect-ratio material profiles. In accordance with an embodiment herein, printing apparatus 100 could be configured to print material profiles of width ranging between 40 μm and 5 mm.

FIG. 1 is merely an example, which should not unduly limit the scope of the claims herein. It is to be understood that the specific designation for printing apparatus 100 is for the convenience of reader and should not to be construed as limiting printing apparatus 100 to specific numbers, shapes, sizes, types, or arrangements of its components. One of ordinary skill in the art would recognize many variations, alternatives, and modifications of embodiments herein. For example, container 102 and nozzle 104 may be integrated together with or without the regulator 108 and controller 110 to form a single unit. In another example, regulator 108 and controller 110 may be located on a separate control box away from container 102.

FIG. 2 illustrates a printing apparatus 200 configured to print a material profile onto a substrate of a photovoltaic device, in accordance with another embodiment herein. Printing apparatus 200 includes a container 202, a plurality of nozzles, shown as a nozzle 204a, a nozzle 204b, a nozzle 204c and a nozzle 204d, and a positive displacement mechanism 206. Nozzle 204a, nozzle 204b, nozzle 204c and nozzle 204d are hereinafter referred to as nozzles 204.

Container 202 is configured to hold a precursor material. With reference to FIG. 2, container 202 has four arms to which nozzles 204 are connected. Each of nozzles 204 has an orifice through which the precursor material is deposited over the substrate.

Positive displacement mechanism 206 is configured to push the precursor material through orifices of nozzles 204 over the substrate. Positive displacement mechanism 206 may, for example, include a piston that is movably positioned within container 102, as shown in FIG. 2. Alternatively, positive displacement mechanism 206 may include a pump that is connected to container 202.

The precursor material is deposited over the substrate as described above, thereby printing the material profile onto the substrate. The precursor material may, for example, be a mixture of various constituents. In an embodiment herein, the precursor material includes a metal-containing substance, whereby the material profile so printed includes one or more electrical conductors. Examples of the metal-containing substance include, but are not limited to, metals, such as silver, copper and gold, metal alloys, such as alloys of silver and gold, metal-containing compounds, and particle mixtures of metals and non-metals.

In accordance with an embodiment herein, a deposit of the precursor material over the substrate has a pre-determined width and a pre-determined cross-sectional area. The pre-determined width and the pre-determined cross-sectional area are user-defined. Printing apparatus 200 may include one or more regulators (not shown in FIG. 2) configured to deposit the precursor material in accordance with pre-determined parameters governing the width and the cross-sectional area of the deposit of the precursor material. These pre-determined parameters may, for example, include at least one of: the position of nozzles 204 with respect to the substrate, the path of movement of nozzles 204 over the substrate, the speed of movement of nozzles 204, the size of the orifices of nozzles 204, the shape of the orifices of nozzles 204, and the rate at which the precursor material is pushed through the orifices of nozzles 204. In addition, printing apparatus 200 may also include one or more controllers (not shown in FIG. 2) configured to define the pre-determined parameters. Details of the pre-determined parameters have been provided in conjunction with FIGS. 3, 4 and 5.

Printing apparatus 200 may further include one or more material regulators (not shown in FIG. 2) configured to alter the properties of the precursor material. The properties of the precursor material are dependent on one or more material parameters. Therefore, the properties of the precursor material may be altered by changing at least one of the material parameters. The material parameters may, for example, include the size of particles in the precursor material, the shape of the particles in the precursor material, and the composition of the precursor material. In accordance with an embodiment herein, printing apparatus 200 could be configured to handle precursor materials of viscosity in the range of 1-300000 centipoises.

Printing apparatus 200 could be configured to print thin and high aspect-ratio material profiles. In accordance with an embodiment herein, printing apparatus 200 could be configured to print material profiles of width ranging between 40 μm and 5 mm.

FIG. 2 is merely an example, which should not unduly limit the scope of the claims herein. It is to be understood that the specific designation for printing apparatus 200 is for the convenience of reader and is not to be construed as limiting printing apparatus 200 to specific numbers, shapes, sizes, types, or arrangements of its components. One of ordinary skill in the art would recognize many variations, alternatives, and modifications of embodiments herein. For example, container 202 may have any number of arms to which separate nozzles are connected. In another example, container 202 and nozzles 204 may be integrated together to form a single unit.

FIG. 3 illustrates a system 300 for printing a material profile onto a substrate 302 of a photovoltaic device, in accordance with an embodiment herein. System 300 includes a platform 304 configured to mount substrate 302 and one or more syringes, shown as a syringe 306, configured to print the material profile onto substrate 302. Syringe 306 includes a container 308, a nozzle 310, and a positive displacement mechanism 312. System 300 also includes one or more regulators, shown as a regulator 314, one or more controllers, shown as a controller 316 and a controller 318, one or more material regulators, shown as a material regulator 320 and a material regulator 322, and one or more indicators, shown as an indicator 324.

Container 308 is configured to hold a precursor material. Container 308 includes a first end and a second end. Nozzle 310 is connected to the first end of container 308. Nozzle 310 has an orifice through which the precursor material is deposited over substrate 302, as shown in FIG. 3.

Positive displacement mechanism 312 is configured to push the precursor material through the orifice of nozzle 310 over substrate 302. Positive displacement mechanism 312 may, for example, include a piston that is movably positioned between the first end and the second end of container 308. Alternatively, positive displacement mechanism 312 may include a pump that is connected to the second end of container 308.

Controller 316 and controller 318 are configured to define pre-determined parameters governing width and cross-sectional area of a deposit of the precursor material. These pre-determined parameters include at least one of: the position of nozzle 310 with respect to substrate 302, the path of movement of nozzle 310 over substrate 302, the speed of movement of nozzle 310, the size of the orifice of nozzle 310, the shape of the orifice of nozzle 310, and the rate at which the precursor material is pushed through the orifice of nozzle 310. In an embodiment herein, controllers 316 and 318 could be mechanical devices or electronic devices.

Regulator 314 is configured to deposit the precursor material in accordance with the pre-determined parameters. Regulator 314 ensures the deposition of the precursor material, based on the pre-determined parameters defined by controller 316 and controller 318.

Material regulator 320 and material regulator 322 are configured to alter the properties of the precursor material. The properties of the precursor material are dependent on one or more material parameters, and may be altered by changing at least one of the material parameters. The material parameters may, for example, include the size of particles in the precursor material, the shape of the particles in the precursor material, the composition of the precursor material, and so forth.

In an embodiment herein, controller 316 and controller 318 could function in conjunction with regulator 314. In an embodiment herein, material regulator 320 and material regulator 322 could function independent of the pre-determined parameters defined by controller 316 and controller 318.

Regulator 314 ensures the deposition of the precursor material in accordance with the pre-determined parameters, while positive displacement mechanism 312 pushes the precursor material through nozzle 310 over substrate 302. Accordingly, nozzle 310 is positioned at a pre-determined position with respect to the substrate 302. The pre-determined position may, for example, depend on the path of movement of nozzle 310 over substrate 302. The pre-determined position may be a starting point of the path of movement of nozzle 310 over substrate 302. Alternatively, the pre-determined position may be a resuming point in between the path of movement of nozzle 310 over substrate 302.

Further, indicator 324 is configured to provide information about the functioning of system 300. For example, indicator 324 may display the current position of nozzle 310 over substrate 302, the complete path of movement of nozzle 310 over substrate 302, the path already covered by nozzle 310 over substrate 302, the speed of movement of nozzle 310, the rate at which the precursor material is pushed through the orifice of nozzle 310, or at least some of the material parameters. In an embodiment herein, indicator 324 may include a set of indicators. This allows system 300 or an operator to monitor functioning of various components of system 300. Accordingly, system 300 or the operator may make appropriate adjustments in at least some of the pre-determined parameters and the material parameters to print a material profile of desired dimensions. It should be understood that such adjustments could either be manual or automatic. System 300 also allows for operator intervention, as and when required.

In an embodiment herein, system 300 could have an auto feedback mechanism (not shown) that could provide inputs to controller 316 and controller 318. The inputs could be related to actual output profile being formed. Controller 316 and/or controller 318 could compute a deviation in desired output profile and actual output profile, and automatically adjust at least some of the pre-determined parameters or the material parameters to print the desired material profile. Moreover, system 300 may be interfaced with one or more Computer Aided Design (CAD) files, and therefore, may be operated in a fully-automated manner.

The precursor material is deposited over substrate 302 to form a deposit 326, as shown in FIG. 3. In accordance with an embodiment herein, system 300 is set up in a surrounding environment that provides suitable conditions for depositing the precursor material. For example, the surrounding environment may provide a sufficiently high temperature that aids proper deposition of deposit 326 (i.e., without allowing deposit 326 to spread over substrate 302). In this way, the material profile is printed onto substrate 302.

The precursor material may, for example, be a mixture of various constituents. In an embodiment herein, the precursor material includes a metal-containing substance, whereby the material profile so printed includes one or more electrical conductors. Examples of the metal-containing substance include, but are not limited to, metals, such as silver, copper and gold, metal alloys, such as alloys of silver and gold, metal-containing compounds, and particle mixtures of metals and non-metals.

Consider, for example, that a material profile is to be printed onto one or more photovoltaic elements. The photovoltaic elements may be pre-coated with an anti-reflective coating to reduce loss of solar energy incident on these photovoltaic elements. The anti-reflective coating may, for example, be made of silicon nitride. In such a case, a precursor material may include a particle mixture of metals and non-metals, where glass-frit may be used as a suitable non-metal. When this precursor material is deposited over the photovoltaic elements, it reacts with the anti-reflective coating to make electrical contact with the photovoltaic elements. In this way, the material profile forms electrical conductors over the photovoltaic elements.

It should be noted here that the material profile is not limited to electrical conductors only, and may include non-electrical features used during manufacturing of the photovoltaic device. For example, the precursor material may include an adhesive that is used to bond various components of the photovoltaic device together. In another example, the precursor material may include a polymeric material that is used to seal various components of the photovoltaic device together.

Deposit 326 of the precursor material over substrate 302 has a pre-determined width and a pre-determined cross-sectional area. The pre-determined width and the pre-determined cross-sectional area are user-defined. Continuing from the above example, the pre-determined width may be defined so as to minimize shadow losses occurring due to presence of the material profile over the photovoltaic elements, while the pre-determined cross-sectional area may be defined so as to reduce the resistance in the electrical conductors.

It should be noted here that various components of system 300 may be located far away from each other. For example, regulator 314, controller 316, controller 318, material regulator 320, material regulator 322, and indicator 324 may be located in a remote control room away from a work room in which syringe 306 prints the material profile onto substrate 302. This allows the operator to operate system 300 from the remote control room.

Consider, for example, that a material profile of small width and large cross-sectional area is to be printed. In order to deposit such a material profile, some of the following adjustments may be performed:

The size of the orifice may be reduced. Nozzle 310 may, for example, have an adjustable orifice. Alternatively, system 300 may include different nozzles with orifices of different shapes and sizes. In such a case, system 300 may also include a nozzle selector for selecting a nozzle with an appropriate orifice that is configured to deposit the precursor material as required.

The shape of the orifice may be chosen such that the width of deposit 326 is reduced while maximizing the cross-sectional area of deposit 326. For example, a nozzle with a rectangular orifice may be used.

The size of the particles in the precursor material may be reduced. Smaller particles may be used to form material profiles of any desired width and cross-sectional area.

The speed of movement of nozzle 310 and/or the rate at which the precursor material is pushed through the orifice of nozzle 310 may be adjusted appropriately. For example, the speed of movement of nozzle 310 may be increased, and/or the rate at which the precursor material is pushed through the orifice of nozzle 310 may be decreased.

The position of nozzle 310 with respect to substrate 302 may be adjusted. For example, positioning nozzle 310 vertically away from substrate 302 may cause the precursor material to extend due to gravity.

It should be appreciated that certain pre-determined parameters and material parameters are inter-related. Therefore, it may be needed to adjust such parameters accordingly.

In accordance with an embodiment herein, system 300 could be configured to handle precursor materials of viscosity in the range of 1-300000 centipoises. In addition, system 300 could be configured to print thin and high aspect-ratio material profiles. In accordance with an embodiment herein, system 300 could be configured to print material profiles of width ranging between 40 μm and 5 mm.

FIG. 3 is merely an example, which should not unduly limit the scope of the claims herein. It is to be understood that the specific designation for system 300 is for the convenience of reader and is not to be construed as limiting system 300 to specific numbers, shapes, sizes, types, or arrangements of its components. One of ordinary skill in the art would recognize many variations, alternatives, and modifications of embodiments herein.

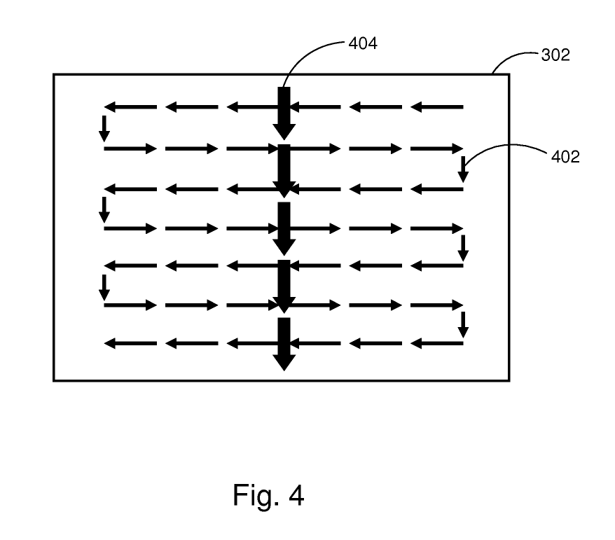

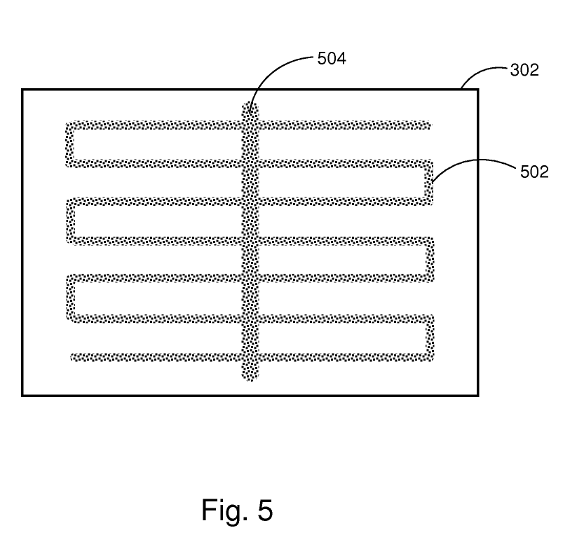

FIG. 4 illustrates the path of movement of nozzle 310 over substrate 302, and FIG. 5 illustrates material profiles so printed onto substrate 302, in accordance with an example embodiment herein. With reference to FIGS. 4 and 5, nozzle 310 moves on a first path 402 to print a first material profile 502, and then moves on a second path 404 to print a second material profile 504. First material profile 502 and second material profile 504 have different dimensions, as shown in FIG. 5. As described earlier, at least some of the pre-determined parameters and the material parameters are altered to print material profiles of different dimensions.

An embodiment herein provides a system for printing a material profile onto a substrate of a photovoltaic device. The system includes printing means for printing the material profile onto the substrate. The printing means include holding means for holding a precursor material and depositing means for depositing the precursor material over the substrate. The depositing means are connected to the holding means, and have an orifice through which the precursor material is deposited over the substrate. The printing means also includes pushing means for pushing the precursor material through the orifice of the depositing means over the substrate.

The system includes means for regulating deposition of the precursor material in accordance with pre-determined parameters governing width and cross-sectional area of the deposit of the precursor material. In addition, the system includes means for defining the per-determined parameters that may include at least one of: the position of the nozzle with respect to the substrate, the path of movement of the nozzle over the substrate, the speed of movement of the nozzle, the size of the orifice of the nozzle, the shape of the orifice of the nozzle, and the rate at which the precursor material is pushed through the orifice of the nozzle.

Further, the system also includes means for altering the properties of the precursor material. The properties of the precursor material are altered by changing at least one of: the size of particles in the precursor material, the shape of the particles in the precursor material, and the composition of the precursor material.

The system may also include means for providing information about the functioning of the system.

Examples of the printing means are, but not limited to, printing apparatus 100, printing apparatus 200, and syringe 306. Examples of the holding means are, but not limited to, container 102, container 202, and container 308. Examples of the depositing means are, but not limited to, nozzle 104, nozzles 204, and nozzle 310. Examples of the pushing means are, but not limited to, positive displacement mechanism 106, positive displacement mechanism 206, and positive displacement mechanism 312.

Examples of the means for regulating deposition are, but not limited to, regulator 108 and regulator 314. Examples of the means for defining are, but not limited to, controller 110, controller 316, and controller 318. Examples of the means for altering the properties are, but not limited to, material regulator 320 and material regulator 322. An example of the means for providing information is, but not limited to, indicator 324.

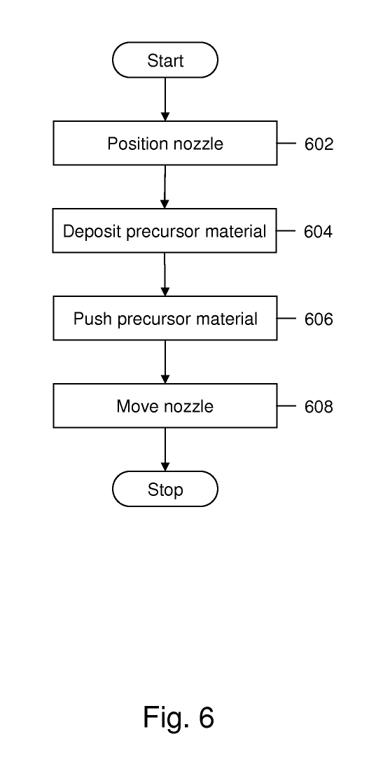

FIG. 6 illustrates a method of printing a material profile onto a substrate of a photovoltaic device, in accordance with an embodiment herein. The method is illustrated as a collection of steps in a logical flow diagram, which represents a sequence of steps that can be implemented in hardware, software, or a combination thereof.

At step 602, a nozzle is positioned at a pre-determined position with respect to the substrate. The pre-determined position may, for example, depend on the path of movement of the nozzle over the substrate. The pre-determined position may be a starting point of the path of movement of the nozzle over the substrate. Alternatively, the pre-determined position may be a resuming point in between the path of movement of the nozzle over the substrate.

At step 604, a precursor material is deposited over the substrate through the nozzle. As mentioned above, a deposit of the precursor material has a pre-determined width and a pre-determined cross-sectional area. The pre-determined width and the pre-determined cross-sectional area are user-defined.

At step 606, the precursor material is pushed through the nozzle over the substrate.

At step 608, the nozzle is moved along its path of movement. While the nozzle moves on its path over the substrate, the nozzle deposits the precursor material over the substrate. Meanwhile, a positive displacement mechanism continuously pushes the precursor material through the nozzle. In accordance with an embodiment herein, steps 604-608 are performed simultaneously.

It should be noted here that steps 602-608 are only illustrative and other alternatives can also be provided where steps are added, one or more steps are removed, or one or more steps are provided in a different sequence without departing from the scope of the claims herein. For example, one or more of the following steps may be added: the step of defining the position of the nozzle with respect to the substrate, the step of defining the path of movement of the nozzle over the substrate, the step of defining the speed of movement of the nozzle, the step of defining the size of an orifice of the nozzle, the step of defining the shape of the orifice of the nozzle, the step of defining the rate at which the precursor material is pushed through the orifice of the nozzle, and so on.

In accordance with an embodiment herein, the method could be configured to handle precursor materials of viscosity in the range of 1-300000 centipoises. In addition, the method could be configured to print thin and high aspect-ratio material profiles. In accordance with an embodiment herein, the method could be configured to print material profiles of width ranging between 40 μm and 5 mm.

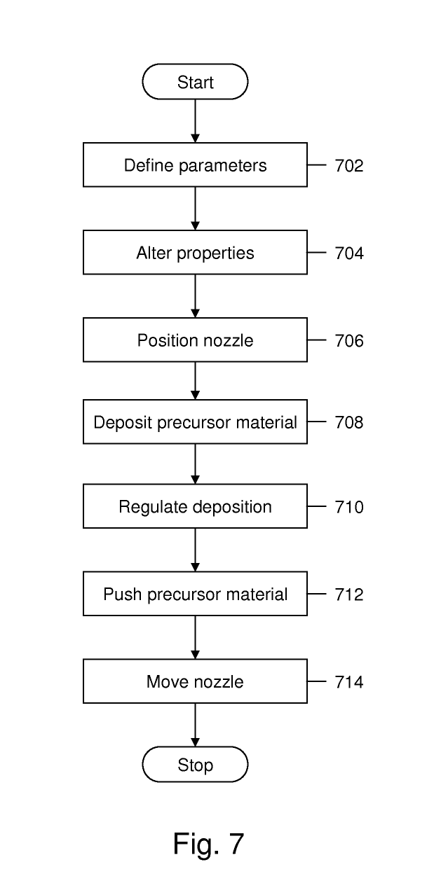

FIG. 7 illustrates a method of printing a material profile onto a substrate of a photovoltaic device, in accordance with another embodiment herein. The method is illustrated as a collection of steps in a logical flow diagram, which represents a sequence of steps that can be implemented in hardware, software, or a combination thereof.

At step 702, pre-determined parameters governing width and cross-sectional area of the material profile are defined. In an embodiment herein, the pre-determined parameters are defined by controller 316 and controller 318. The pre-determined parameters may, for example, include at least one of: the position of a nozzle with respect to the substrate, the path of movement of the nozzle over the substrate, the speed of movement of the nozzle, the size of an orifice of the nozzle, the shape of the orifice of the nozzle, and the rate at which a precursor material is pushed through the orifice of the nozzle.

At step 704, the properties of the precursor material are altered to print a material profile of desired dimensions. In an embodiment herein, the properties of the precursor material are altered by material regulator 320 and material regulator 322. The properties of the precursor material may, for example, be altered by changing at least one of: the size of particles in the precursor material, the shape of the particles in the precursor material, and the composition of the precursor material.

At step 706, a nozzle is positioned at a pre-determined position with respect to the substrate. In an embodiment herein, the nozzle is positioned at a pre-determined position with respect to the substrate by regulator 314. The pre-determined position may, for example, depend on the path of movement of the nozzle over the substrate. The pre-determined position may be a starting point of the path of movement of the nozzle over the substrate. Alternatively, the pre-determined position may be a resuming point in between the path of movement of the nozzle over the substrate.

At step 708, the precursor material is deposited over the substrate through the nozzle.

At step 710, the deposition of the precursor material is regulated in accordance with the pre-determined parameters defined at step 702. In an embodiment herein, the deposition of the precursor material is regulated by regulator 314.

At step 712, the precursor material is pushed through the nozzle over the substrate.

At step 714, the nozzle is moved along its path of movement. The nozzle is moved to new positions on its path of movement, while the precursor material is deposited over the substrate. Meanwhile, a positive displacement mechanism continuously pushes the precursor material through the nozzle.

It should be noted here that steps 702-714 are illustrative and other alternatives can also be provided where steps are added, one or more steps are removed, or one or more steps are provided in a different sequence without departing from the scope of the claims herein. For example, step 702 and step 704 may be performed simultaneously. Similarly, step 708, step 710, step 712 and step 714 may also be performed simultaneously.

In accordance with an embodiment herein, the method could be configured to handle precursor materials of viscosity in the range of 1-300000 centipoises. In addition, the method could be configured to print thin and high aspect-ratio material profiles. In accordance with an embodiment herein, the method could be configured to print material profiles of width ranging between 40 μm and 5 mm.

Embodiments herein provide a printing apparatus, method and system for printing a material profile of desired dimensions. In order to print the material profile of desired dimensions, at least some of pre-determined parameters and material parameters are adjusted. The printing method does not call for substantial modifications in a precursor material, and therefore, is independent of the viscosity of the precursor material. The printing method is configured to handle precursor materials of different viscosities.

In addition, the printing method facilitates non-contact printing, and does not exert any pressure on the substrate. Therefore, the printing method reduces chances of breakage as well as instances of micro-crack introduction during printing.

The printing method is configured to print thin and high aspect-ratio material profiles. Material profiles of width ranging between 40 μm and 50 μm may be achieved. This results in reduction of shadow losses, which consequently, improves the efficiency of photovoltaic devices by 0.2-0.3% absolute.

Moreover, the system may be interfaced with one or more CAD files, and therefore, may be operated in a fully-automated manner. The system also allows for operator intervention, as and when required.

Furthermore, the printing method prints the material profile in a single process, and does not require multiple processes. The printing method neither uses another process for increasing the height of fingers, nor calls for substantial modification of the material profile. In this way, the printing method helps achieve high overall yield, and therefore, is suitable for mass manufacturing.

This application may disclose several numerical range limitations that support any range within the disclosed numerical ranges even though a precise range limitation is not stated verbatim in the specification because the embodiments of the present invention could be practiced throughout the disclosed numerical ranges. Finally, the entire disclosure of the patents and publications referred in this application, if any, are hereby incorporated herein in entirety by reference.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

What is claimed as being new and desired to be protected by Letters Patent of the United States is as follows:

1. A printing apparatus configured to print a material profile onto a substrate, said printing apparatus comprising:
a container configured to hold a precursor material, said container having a first end and a second end;
a nozzle connected to said first end of said container, said nozzle defining an orifice configured to deposit said precursor material over said substrate;
a positive displacement mechanism configured to push said precursor material through said orifice of said nozzle over said substrate; and
one or more regulators configured to deposit said precursor material in accordance with pre-determined parameters governing width and cross-sectional area of said precursor material deposited over said substrate, such that said precursor material deposited over said substrate has a pre-determined width and a pre-determined cross-sectional area.

2. The printing apparatus of claim 1, wherein said material profile comprises one or more electrical conductors.

3. The printing apparatus of claim 1, wherein said positive displacement mechanism comprises a piston that is movably positioned between said first end and said second end of said container.

4. The printing apparatus of claim 1, wherein said substrate is a substrate of a photovoltaic device.

5. The printing apparatus of claim 1, wherein said pre-determined parameters comprise at least one of: the position of said nozzle with respect to said substrate, the path of movement of said nozzle over said substrate, the speed of movement of said nozzle, the size of said orifice of said nozzle, the shape of said orifice of said nozzle, and the rate at which said precursor material is pushed through said orifice of said nozzle.

6. The printing apparatus of claim 1 further comprising one or more controllers configured to define said pre-determined parameters.

7. The printing apparatus of claim 1 further comprising one or more material regulators configured to alter the properties of said precursor material, said properties being altered by changing at least one of: the size of particles in said precursor material, the shape of said particles in said precursor material, and the composition of said precursor material.

8. The printing apparatus of claim 1 further comprising one or more indicators configured to provide information about the functioning of the printing apparatus.

9. The printing apparatus of claim 1 is configured to handle precursor materials of viscosity in the range of 1-300000 centipoises.

10. The printing apparatus of claim 1 is configured to print material profiles of width ranging between 40 μm and 5 mm.

11. A system for printing a material profile onto a substrate of a photovoltaic device, said system comprising:
a platform configured to mount said photovoltaic device; and
a syringe configured to print said material profile over said substrate, said syringe comprising:
a container configured to hold a precursor material, said container having a first end and a second end;
a nozzle connected to said first end of said container, said nozzle defining an orifice configured to deposit said precursor material having a pre-determined width and a pre-determined cross-sectional area over said substrate; and
a positive displacement mechanism configured to push said precursor material through said orifice of said nozzle over said substrate.

12. The system of claim 11, wherein said material profile comprises one or more electrical conductors.

13. The system of claim 11, wherein said positive displacement mechanism comprises a piston that is movably positioned between said first end and said second end of said container.

14. The system of claim 11 further comprising one or more regulators configured to ensure deposition of said precursor material in accordance with pre-determined parameters governing width and cross-sectional area of said precursor material deposited over said substrate.

15. The system of claim 14, wherein said pre-determined parameters comprise at least one of: the position of said nozzle with respect to said substrate, the path of movement of said nozzle over said substrate, the speed of movement of said nozzle, the size of said orifice of said nozzle, the shape of said orifice of said nozzle, and the rate at which said precursor material is pushed through said orifice of said nozzle.

16. The system of claim 14 further comprising one or more controllers configured to define said pre-determined parameters.

17. The system of claim 11 further comprising one or more material regulators configured to alter the properties of said precursor material, said properties being altered by changing at least one of: the size of particles in said precursor material, the shape of said particles in said precursor material, and the composition of said precursor material.

18. The system of claim 11 further comprising one or more indicators configured to provide information about the functioning of the system.

19. The system of claim 11 is configured to handle precursor materials of viscosity in the range of 1-300000 centipoises.

20. The system of claim 11 is configured to print material profiles of width ranging between 40 μm and 5 mm.
